(19) United States
(12) Patent Application Publication
(10) Pub. No.: US 2013/0169268 A1
(43) Pub. Date: Jul. 4, 2013

(54) Schottky Diode Radio Frequency Detector Probe With Amplitude Linearity Compensation

(71) Applicant: Benjamin Eng, JR., Everett, WA (US)

(72) Inventor: Benjamin Eng, JR., Everett, WA (US)

(73) Assignee: Fluke Corporation, Everett, WA (US)

(21) Appl. No.: 13/339,676

(22) Filed: Dec. 29, 2011

(51) Int. Cl. G01R 19/22

(52) U.S. Cl. 324/119

(57) ABSTRACT

A passive radio frequency probe that can detect low level RF signals is disclosed. Schottky diodes are used in the probe to convert alternating current (AC) signals to direct current (DC) signals on a one-to-one basis within a given tolerance. The probe is used with a DC voltmeter to permit measurements of radio frequency signals.

### BACKGROUND

Multimeters are useful for measuring signals that typically do not have a frequency above approximately 100 kHz. Signals having frequencies above this range cannot accurately be detected by the multimeter.

A high frequency detector probe that converts an alternating current (AC) signal to a direct current (DC) output can be used in conjunction with a DC voltmeter. The DC voltmeter can measure the DC output from the high frequency detector probe, even when the input signals have frequencies greater than 100 kHz.

Germanium diodes have been used in high frequency detector probes and have performed well. However, germanium diodes are no longer being produced. Historically, germanium diodes have been used for amplitude modulation (AM), frequency modulation (FM), and television video detectors. However, today AM, FM, and television detection or demodulation is performed in integrated circuits, and discrete germanium diodes are no longer used. Thus, discrete germanium diodes are no longer being produced, and an alternative implementation of the detector probe is needed that does not use germanium diodes and has similar or better amplitude and frequency response performance.

Current high frequency detector probes can be improved to have a flatter frequency response below 100 MHz and a flatter or more linear amplitude response over a wider range of low input voltages.

### BRIEF DESCRIPTION OF THE DRAWINGS

Examples of a radio frequency (RF) detector probe using Schottky diodes and having amplitude linearity compensation are illustrated in the figures. The examples and figures are illustrative rather than limiting.

FIG. 1A shows a block diagram of an example environment in which an RF detector probe is used.

FIG. 1B shows a block diagram in which a high frequency probe is part of a voltmeter that includes circuitry for a DC voltmeter.

FIG. 2A shows a schematic of a detector probe that uses a germanium diode.

FIG. 2B shows a graph of the amplitude response of the germanium diode based detector probe.

FIG. 2C shows a graph of the frequency response of the germanium diode-based detector probe.

FIG. 3 shows a graph of the amplitude response of a detector probe that substitutes a Schottky diode directly for the germanium diode.

FIG. 4A shows a schematic of a detector probe that uses a Schottky diode-based voltage doubler.

FIG. 4B shows a graph of the amplitude response of the detector probe that uses a Schottky diode-based voltage doubler.

FIG. 4C shows a graph of the frequency response of the detector probe that uses a Schottky diode-based voltage doubler.

FIG. 5 is a flow diagram illustrating an example process of operating an RF detector probe that uses a Schottky diode-based voltage doubler.

FIG. 6A shows a schematic of a detector probe that uses a biased Schottky diode.

FIG. 6B is a flow diagram illustrating an example process of operating an RF detector probe that uses a biased Schottky diode.

### DETAILED DESCRIPTION

A passive radio frequency probe that can detect low level RF signals at frequencies as high as 500 MHz is disclosed. Schottky diodes are used in the probe to convert alternating current (AC) signals to direct current (DC) signals on a one-to-one basis for an input voltage range between 0.25 volt (V) root means square (rms) to 30 V rms. The accuracy of the conversion is ±1.0 decibels (dB0 for an AC input between 0.25 V rms and 0.5 V rms and ±0.5 dB for an AC input between 0.5 V rms and 30 V rms. The probe can be used with a DC voltmeter to permit measurements of radio frequency signals.

Various aspects and examples of the invention will now be described. The following description provides specific details for a thorough understanding and enabling description of these examples. One skilled in the art will understand, however, that the invention may be practiced without many of these details. Additionally, some well-known structures or functions may not be shown or described in detail, so as to avoid unnecessarily obscuring the relevant description.

The terminology used in the description presented below is intended to be interpreted in its broadest reasonable manner, even though it is being used in conjunction with a detailed description of certain specific examples of the technology. Certain terms may even be emphasized below; however, any terminology intended to be interpreted in any restricted manner will be overtly and specifically defined as such in this Detailed Description section.

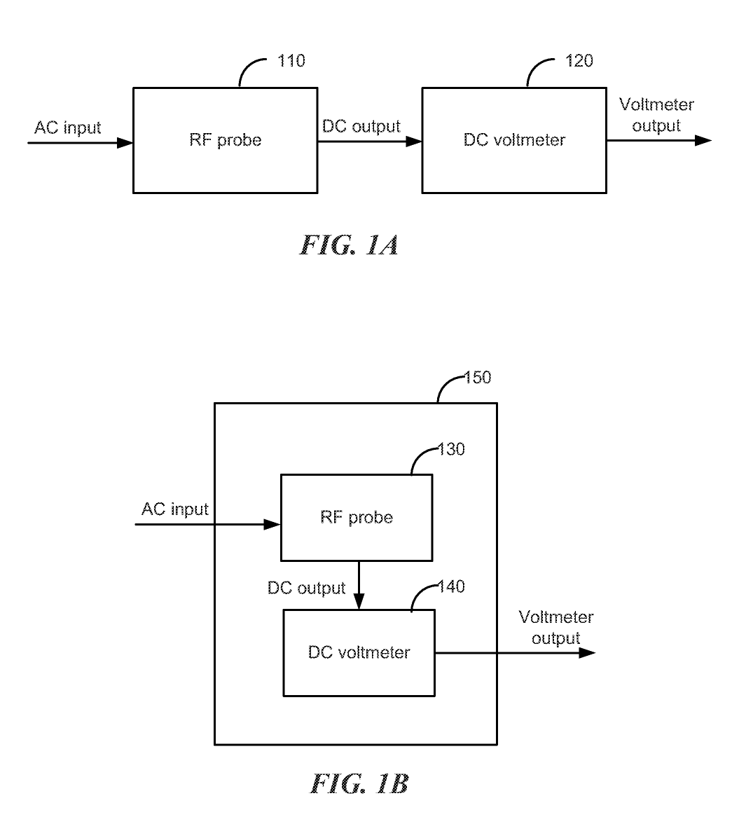

FIG. 1A shows a block diagram of an example environment in which an RF detector probe is used. The RF detector probe 110, to be described below, converts an AC signal to a DC signal on a one-to-one basis, for example, a 1.0 V rms input sine wave is scaled to a 1.0 V DC output signal. Further, the RF probe 110 accepts a wide input voltage range from 0.25 V rms to 30 V rms. The DC output from the RF detector probe 110 is sent to a DC voltmeter 120, thus enabling the DC voltmeter 120 to function as a high frequency AC voltmeter. In one embodiment, the output of the RF probe 110 is a test lead that has a form suitable for plugging into an input terminal of the DC voltmeter 120, such as a banana plug.

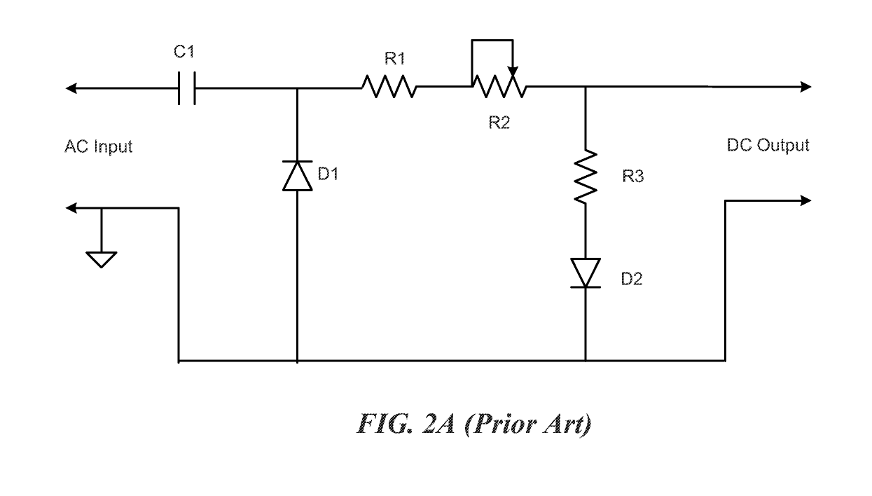

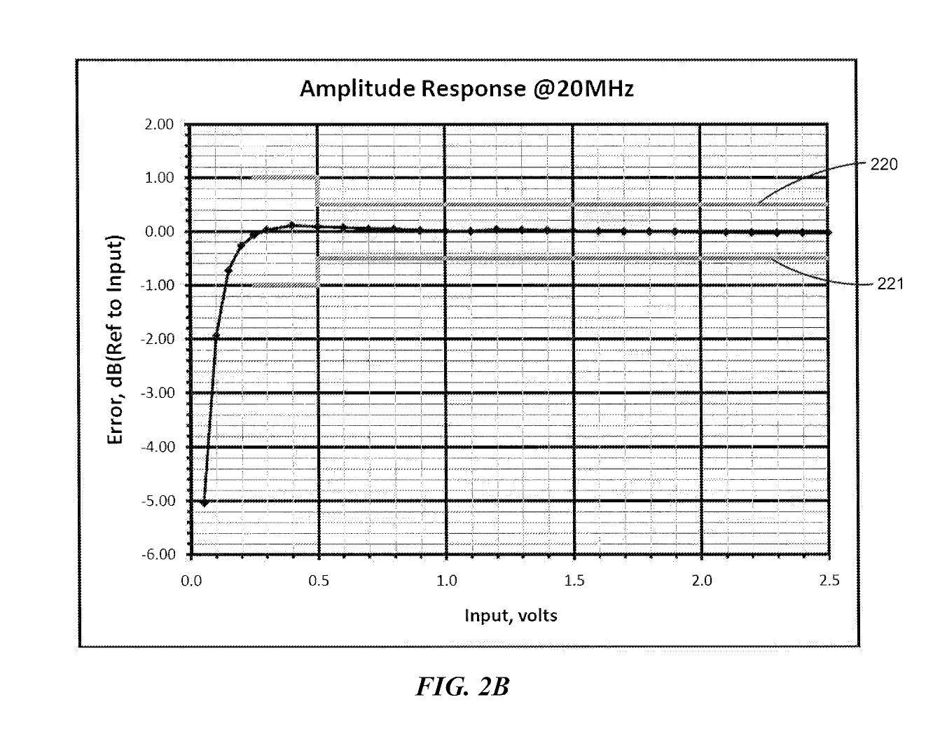

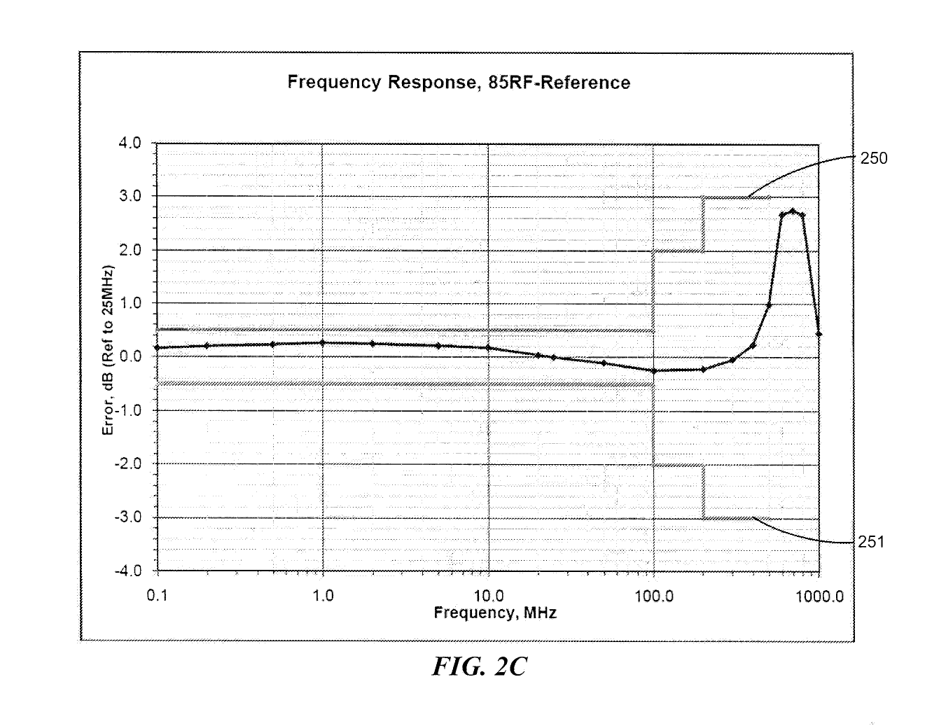

FIG. 1B shows a block diagram in which the RF probe 130 is part of a voltmeter 150 that includes circuitry for a DC voltmeter 140. For example, the voltmeter 150 can have a high frequency setting, where a high frequency input signal is directed to the RF probe circuitry before being measured by the DC voltmeter circuitry 140. Alternatively, the voltmeter can be a dedicated AC voltmeter that works best with signals having a frequency greater than approximately 100 kHz. The frequency response of signals below approximately 100 kHz is limited by the value of the input capacitor (e.g., capacitor C1 in FIG. 2A), and the value of the input capacitor is selected to limit the energy permitted to enter the probe when the probe is coupled to a point that has a DC level of up to 250 V, such as when a probe is used to trace an RF signal in an RF amplifier, to prevent damage to the germanium diode.

FIG. 2A shows a schematic of a known detector probe, which uses a germanium diode. Capacitor C1 and germanium diode D1 form a capacitor-coupled rectifier circuit that responds to the peak value of the input waveform. The output of the probe is calibrated to be a positive DC voltage that corresponds to the rms value of a sine wave input. Resistors R1, R2, R3 and silicon diode D2 form a divider to scale the DC output when the probe output is coupled to a DC voltmeter having a 10 MΩ input resistance. Further, silicon diode D2 compensates for the low level linearity error caused by germanium diode D1.

The germanium-based detector probe shown in FIG. 2A is used to allow a DC voltmeter with an input impedance of 10 MΩ to be used as a high frequency RF voltmeter for high frequency signals from 100 kHz to 500 MHz. The probe converts AC signals to DC signals on a one-to-one basis over a range of 0.25 V rms to 30 V rms. The accuracy of the one-to-one conversion ratio is ±1.0 dB for input voltages less than 0.5 V rms and ±0.5 dB for input voltages greater than 1.0 V rms. The probe's DC output is calibrated to be equivalent to the rms value of a sine wave input.

FIG. 2B shows a graph of the amplitude response of the germanium diode based detector probe for low input voltages. The horizontal lines 220, 221 show the upper and lower allowable limits, respectively, according to the conversion ratio accuracy specification. The amplitude response of the germanium diode based detector probe is within the allowable limits for a range of operating temperatures between 5° C. and 35° C.

FIG. 2C shows a graph of the frequency response of the germanium diode-based detector probe from 0.1 MHz to 1000 MHz. The limit lines 250, 251 show the frequency response specifications.

A typical germanium diode has a forward voltage of less than 0.08 volts at 10 μA. A low forward voltage is needed to detect low level signals. If the forward voltage is too high, the output of a peak detector will be zero or very low for small input signals because most of the input voltage will be developed across the diode and not appear at the output. The forward voltage of a Schottky diode has a forward voltage rating of approximately 0.2 V, close to that of the germanium diode. Thus, replacing the Schottky diode for the germanium diode in the schematic shown in FIG. 2A was tried.

For input voltages greater than 1.0 V, the probe functioned in a similar manner to the germanium diode-based detector probe and met the ratio accuracy specification. However, the amplitude response for input voltages between 0.25 V rms and 0.7 V rms did not meet the specifications. The amplitude linearity was poor, and the peak detector's output level was too low for the passive amplitude compensation circuit to allow the Schottky substitution probe circuit to meet the ratio accuracy specifications given above.

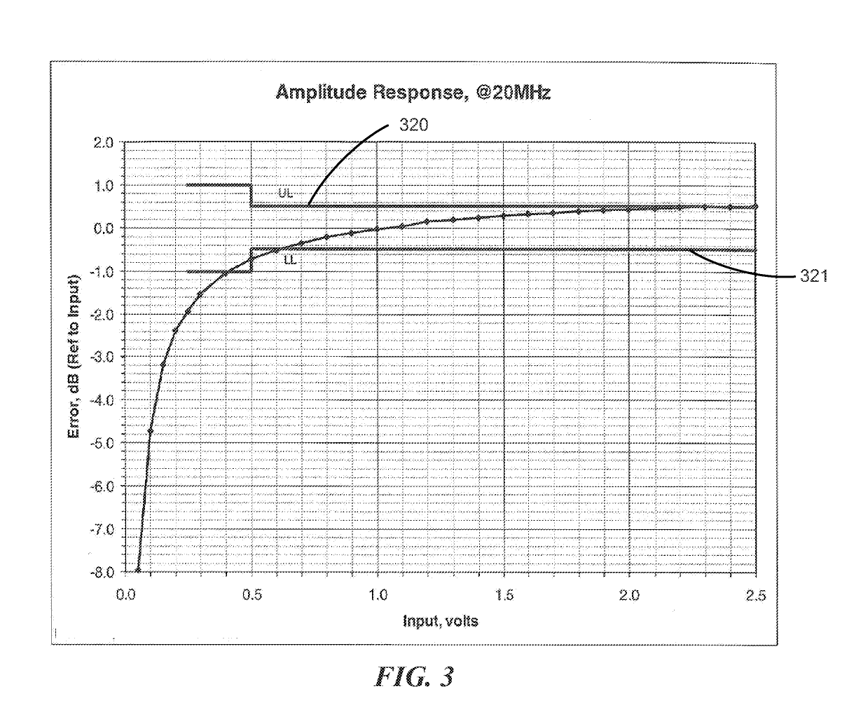

FIG. 3 shows a graph of the amplitude response of a detector probe that substitutes a Schottky diode directly for the germanium diode. The horizontal lines 320, 321 show the upper and lower allowable limits, respectively, according to the conversion ratio accuracy specification. The limits 320, 321 are the same as the limits 220, 221 shown in FIG. 2B. For an input signal of 0.4 V rms, the amplitude response is low by approximately 1 dB after the probe has been correctly calibrated for providing a DC output of 1.0 V for an input voltage of 1.0 V rms.

Schottky diodes exist that have a lower forward voltage characteristic, similar to that of the germanium diode, and meet the amplitude response specification at low input levels. However, the reverse breakdown voltage for these types of Schottky diodes is too low to work at high input voltage levels of 25 V rms to 30 V rms. A minimum reverse breakdown voltage of at least 42.2 V is needed, and the Schottky diodes that have a very low forward voltage typically have a reverse breakdown voltage between 6 V and 10 V.

A Biased Schottky Diode-Based Detector Probe

Using a Schottky diode that has a higher forward voltage as a substitute for the germanium diode is possible without causing a problem at very low input voltage levels if the diode is biased using a battery or other current or voltage source. In one embodiment, a relatively low bias current can be used to ensure sufficiently long operating times with a battery.

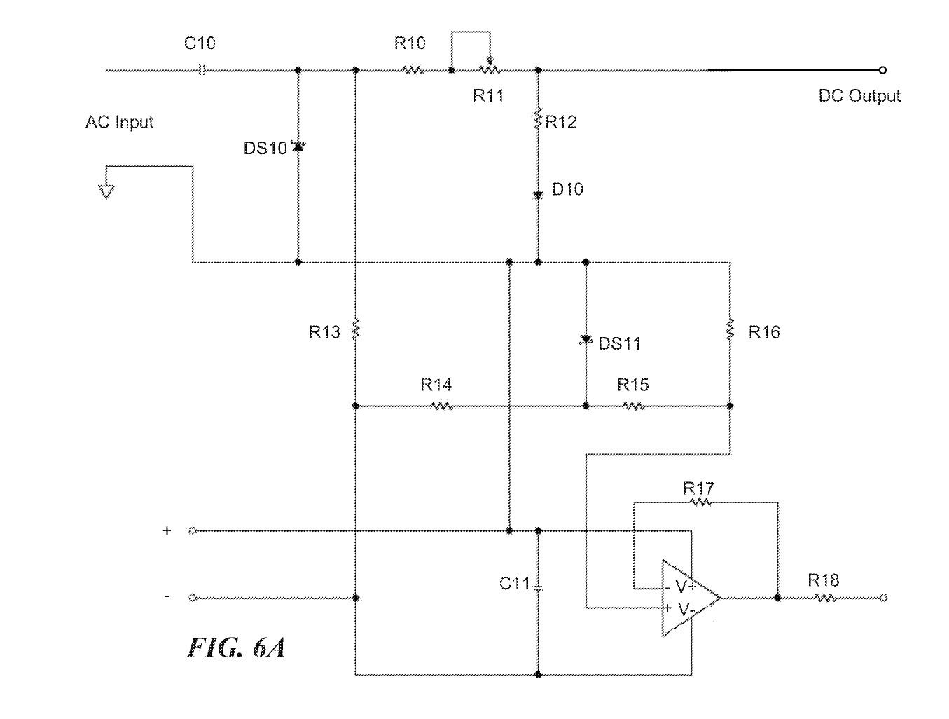

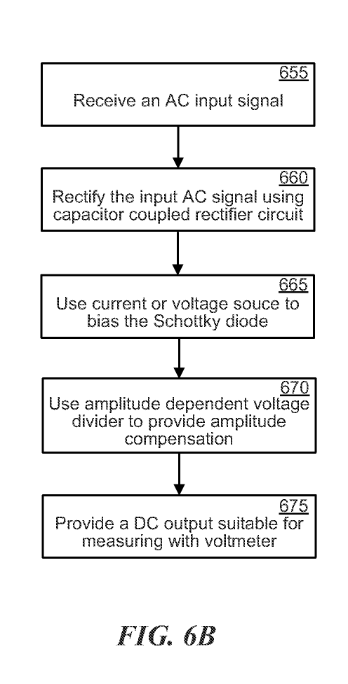

FIG. 6A shows a design of one embodiment of the detector probe that uses a biased Schottky diode. A relatively low bias current is used to increase the operating time of the batteries. The design uses a compensation circuit to provide amplitude linearity and an offset circuit to cancel the offset generated by the bias current. In one embodiment, a much higher bias current can be used to reduce the amount of amplitude compensation correction, but the battery required to power the probe would necessarily be larger.

Amplitude compensation is performed by changing the divider ratio at the output of the peak detector circuit that includes capacitor C10, Schottky diode DS10, and resistors R10 and R11. Diode D10 turns on at approximately 0.5 V and connects resistor R12 in parallel with the 10 MΩ input resistance of the multimeter when the output voltage of the peak detector approaches 0.5 V, thus changing the output scale factor.

The bias current to turn on the peak detector diode DS10 is supplied through resistor R13 from the probe power supply source. The same current is supplied to offset Schottky diode DS12 through resistor R14. The voltage generated across Schottky diode DS12 is the offset cancellation voltage that makes the output of the probe zero when no RF signal is applied to the probe. The operational amplifier is a unity gain buffer amplifier that buffers the scaled output voltage generated across Schottky diode DS12.

FIG. 6B is a flow diagram illustrating an example process of operating an RF detector probe that uses a biased Schottky diode. At block 655, the RF probe receives an AC input signal. The AC signal can have frequencies in the RF frequency range, up to 500 MHz.

At block 660, the RF probe rectifies the AC input signal using a capacitor coupled rectifier circuit, where the rectifier circuit includes a Schottky diode. The probe has a current or voltage source that is used to bias the Schottky diode at block 665.

Then at block 670 the RF probe provides amplitude compensation by using an amplitude dependent voltage divider.

The RF probe provides a DC output suitable for measuring with a DC voltmeter at block 675. In one embodiment, the RF probe is adjusted to provide the DC output to a DC voltmeter that has an input impedance of 10 MΩ.

A Schottky Diode-Based Doubler Circuit

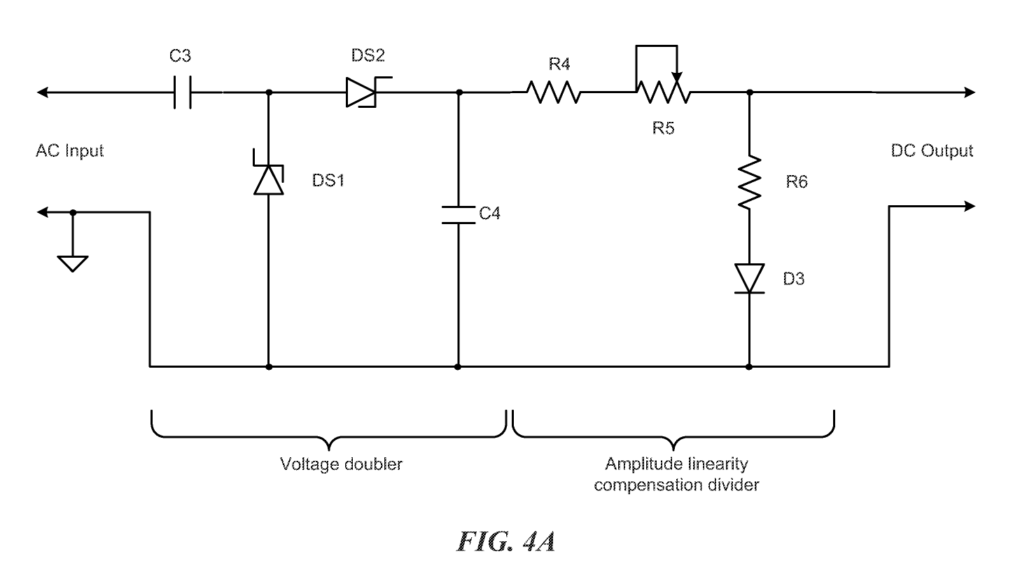

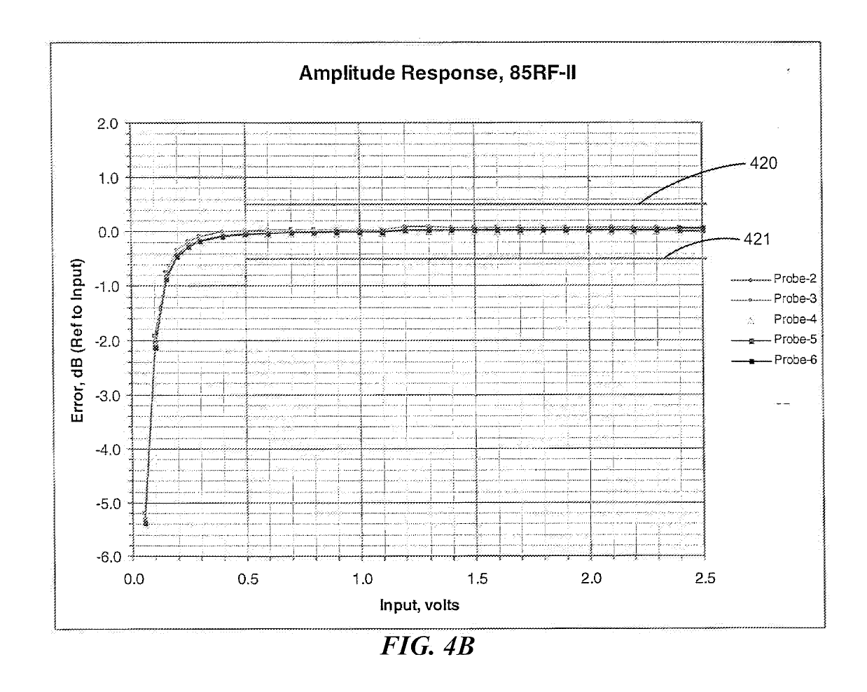

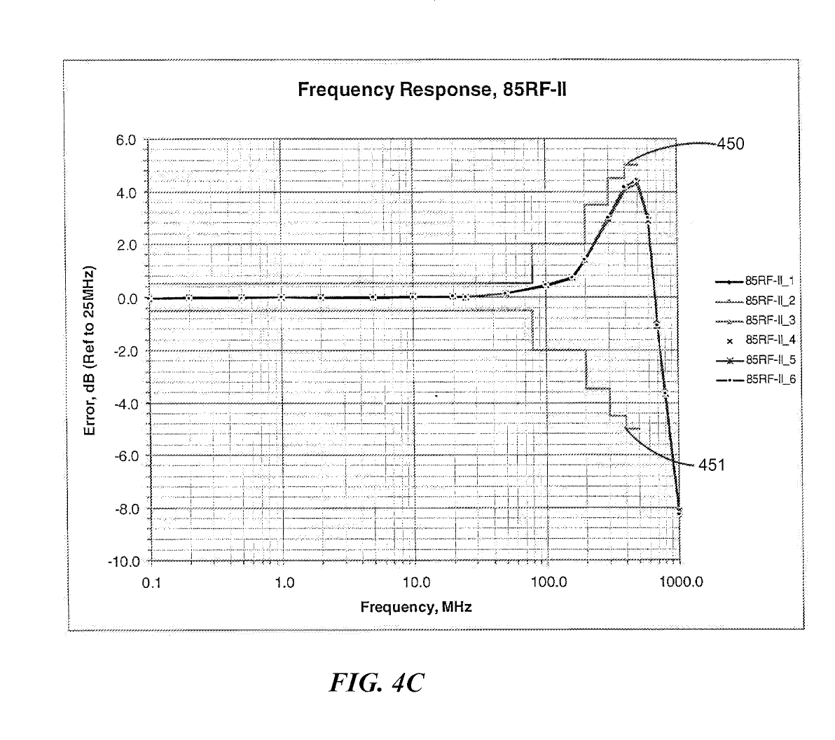

In one embodiment, two Schottky diodes in a doubler circuit are used to raise the average voltage level of the AC input to a higher voltage, and an amplitude compensation circuit is used to enhance the linearity of the amplitude response of the doubler circuit. FIG. 4A shows a schematic of a detector probe that uses this configuration. The detector probe circuit includes a voltage doubler and an amplitude linearity compensation divider. This detector probe configuration provides a flatter frequency response below 100 MHz than the germanium-based detector probe and also a more linear amplitude response down to input voltages of 0.25 V rms.

The voltage doubler design includes capacitors C3 and C4 and Schottky diodes DS1 and DS2. For symmetrical sine waves around zero volts, the negative half cycle of the input sine wave charges capacitor C3 to the negative peak, and on the positive half cycle of the input sine wave, the voltage across capacitor C3 added to the positive input signal peak charges capacitor C4 to the sum of the negative and positive peaks. As a result, the voltage across capacitor C4 will be the peak to peak value of the input sine wave signal. The DC level is twice the DC level generated by a single diode peak detector, as with the original germanium diode-based detector probe.

The amplitude linearity compensation divider includes resistors R4, R5, and R6 and silicon diode D3. This portion of the circuit enhances the amplitude linearity of the probe. As is typical with silicon diodes, when a voltage is applied across the diode in the forward direction, the diode does not turn on until about 0.5 V. Resistors R4, R5, and R6 form a voltage divider. The voltage divider is amplitude dependent because for very low input signals less than 0.5 V, the diode D3 does not turn on.

Potentiometer R5 is adjusted so that when 1 V rms is applied as the input signal, 1 V DC appears at the output of the circuit. Resistor R6 is selected so that at low input voltages the divider ratio of the circuit maintains an output within the specification of ±1.0 dB between 0.25 V rms and 1.0 V rms.

FIG. 4B shows a graph of the amplitude response of the detector probe that uses a Schottky diode-based voltage doubler. The results of five different detector probes are shown in FIG. 4B. The limits 420, 421 are the same as the limits 220, 221 shown in FIG. 2B that correspond to the conversion ratio accuracy specification for the probe. The amplitude response is well within the requirements for the probe. Further, the amplitude response of this detector probe is essentially the same at low input voltages near 0.25 V (shown in FIG. 4B) as compared to the amplitude response for the germanium-based detector probe (shown in FIG. 2B).

FIG. 4C shows a graph of the frequency response of the detector probe that uses a Schottky diode-based voltage doubler. The results of six different detector probes are shown in FIG. 4C. The lines 450, 451 show the upper and lower allowable frequency response limits, respectively. The specification requires the frequency response of the probe relative to 25 MHz to be ±0.5 dB for an AC input frequency between 100 kHz and 100 MHz, ±2.0 dB for an AC input frequency between 100 MHz and 200 MHz, and the specification is relaxed in gradually increasing steps up to 5.0 dB for an AC input frequency between 200 MHz and 500 MHz.

It should be noted that the detector probe using the Schottky diode-based doubler circuit shown in FIG. 4A has a frequency response from 0.1 MHz to 100 MHz, that is flat to within about 0.2 dB. Additionally, the flatness of the frequency response is similar to that of the detector probe that uses the germanium diode (shown in FIG. 2C).

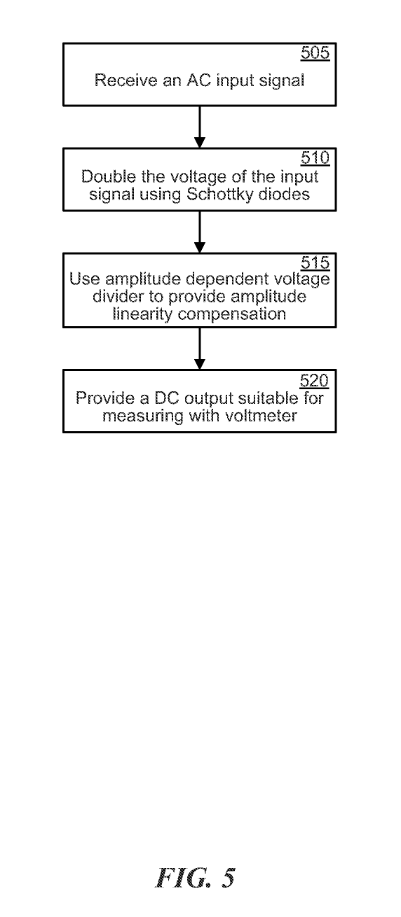

FIG. 5 is a flow diagram illustrating an example process of operating an RF detector probe that uses a Schottky diode-based voltage doubler. At block 505, the RF probe receives an AC input signal. The AC signal can have frequencies in the RF frequency range, up to 500 MHz.

At block 510, the RF probe doubles the voltage of the input signal using a Schottky diode-based voltage doubler.

Then at block 515, the RF probe uses an amplitude dependent voltage divider to provide amplitude linearity compensation.

The RF probe provides a DC output suitable for measuring with a DC voltmeter at block 520. In one embodiment, the RF probe is adjusted to provide the DC output to a DC voltmeter that has an input impedance of 10 MΩ.

### CONCLUSION

Unless the context clearly requires otherwise, throughout the description and the claims, the words “comprise,” “comprising,” and the like are to be construed in an inclusive sense (i.e., to say, in the sense of “including, but not limited to”), as opposed to an exclusive or exhaustive sense. As used herein, the terms “connected,” “coupled,” or any variant thereof means any connection or coupling, either direct or indirect, between two or more elements. Such a coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. While processes or blocks are presented in a given order in this application, alternative implementations may perform routines having steps performed in a different order, or employ systems having blocks in a different order. Some processes or blocks may be deleted, moved, added, subdivided, combined, and/or modified to provide alternative or subcombinations. Also, while processes or blocks are at times shown as being performed in series, these processes or blocks may instead be performed or implemented in parallel, or may be performed at different times. Further any specific numbers noted herein are only examples. It is understood that alternative implementations may employ differing values or ranges.

The various illustrations and teachings provided herein can also be applied to systems other than the system described above. The elements and acts of the various examples described above can be combined to provide further implementations of the invention.

Any patents and applications and other references noted above, including any that may be listed in accompanying filing papers, are incorporated herein by reference. Aspects of the invention can be modified, if necessary, to employ the systems, functions, and concepts included in such references to provide further implementations of the invention.

These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

While certain aspects of the invention are presented below in certain claim forms, the applicant contemplates the various aspects of the invention in any number of claim forms. For example, while only one aspect of the invention is recited as a means-plus-function claim under 35 U.S.C. §112, sixth paragraph, other aspects may likewise be embodied as a means-plus-function claim, or in other forms, such as being embodied in a computer-readable medium. (Any claims intended to be treated under 35 U.S.C. §112, ¶6 will begin with the words “means for.”) Accordingly, the applicant reserves the right to add additional claims after filing the application to pursue such additional claim forms for other aspects of the invention.

What is claimed is:

1. A radio frequency (RF) probe comprising:
a voltage raising circuit configured to receive an alternating current (AC) input and raise an average voltage level of the AC input; and
an amplitude linearity compensation circuit configured to provide amplitude linearity compensation for an output of the voltage raising circuit,
wherein the RF probe converts the AC input to a direct current (DC) output.

2. The RF probe of claim 1, wherein the voltage raising circuit includes a Schottky diode.

3. The RF probe of claim 1, wherein the voltage raising circuit is a voltage doubler circuit.

4. The RF probe of claim 3, wherein the voltage doubler circuit comprises a first Schottky diode, a second Schottky diode, a first capacitor, and a second capacitor, and further wherein a cathode terminal of the first Schottky diode is coupled to an anode terminal of the second Schottky diode and a second terminal of the first capacitor, a cathode terminal of the second Schottky diode is coupled to a first terminal of the second capacitor, and a second terminal of the second capacitor and an anode terminal of the first Schottky diode are coupled to ground, wherein the AC input is coupled between a first terminal of the first capacitor and ground.

5. The RF probe of claim 1, wherein the amplitude linearity compensation circuit is an amplitude selective voltage divider.

6. The RF probe of claim 5, wherein the amplitude selective voltage divider includes a diode.

7. The RF probe of claim 1, wherein the amplitude linearity compensation circuit comprises a first resistor, a second resistor, a third resistor, and a silicon diode, wherein a second terminal of the first resistor is coupled to a first terminal of the second resistor, a second terminal of the second resistor is coupled to a first terminal of the third resistor, a second terminal of the third resistor is coupled to an anode terminal of the silicon diode, and a cathode terminal of the silicon diode is coupled to ground, and further wherein the DC output is between a node and ground, wherein the node is between the second terminal of the second resistor and the first terminal of the third resistor.

8. A radio frequency (RF) probe comprising:
means for raising an average voltage level of an alternating current (AC) input voltage; and
means for compensating for an amplitude linearity error caused by the means for raising an average voltage level of the AC input voltage;
wherein the RF probe converts an AC input to a direct current (DC) output.

9. The probe of claim 8, wherein the means for compensating for an amplitude linearity error caused by the means for raising the average voltage level of the AC input voltage comprises a diode in a voltage divider.

10. The probe of claim 8, wherein the means for raising the average voltage level of the AC input voltage includes a Schottky diode.

11. The probe of claim 8, wherein the means for raising the average voltage level of the AC input voltage includes a Schottky diode in a voltage doubler circuit.

12. A method of converting an alternating current (AC) input signal to a direct current (DC) output signal, comprising:
receiving the AC input signal;
using a voltage raising circuit configured to raise an average voltage level of the AC input signal;
using an amplitude linearity compensation circuit configured to provide amplitude linearity compensation for the AC input signal with the raised DC level.

13. The method of claim 12, wherein the voltage raising circuit includes a Schottky diode.

14. The method of claim 13, wherein the voltage raising circuit includes a Schottky diode in a voltage doubler circuit.

15. The method of claim 12, wherein the amplitude linearity compensation circuit is an amplitude selective voltage divider that includes a diode.

16. A radio frequency (RF) probe comprising:
a peak detector;
an amplitude linearity compensation circuit configured to provide amplitude linearity compensation for an output of the peak detector; and
a power supply configured to provide a bias current to the peak detector,
wherein the RF probe converts an alternating current (AC) input to a direct current (DC) output.

17. The RF probe of claim 16, wherein the peak detector includes a Schottky diode.

18. The probe of claim 16, wherein the amplitude linearity compensation circuit is an amplitude selective voltage divider that includes a diode.

19. A method of converting an alternating current (AC) input signal to a direct current (DC) output signal, comprising:
receiving the AC input signal;
using a peak detector for the AC input signal;
using an amplitude dependent voltage divider configured to provide amplitude linearity compensation for the peak detector;
using a bias current with the peak detector.

20. The method of claim 19, wherein the peak detector includes a Schottky diode.

21. An apparatus comprising:
a high frequency probe configured to convert an alternating current (AC) probe input to a direct current (DC) probe output; and
a DC voltmeter circuit configured to measure the DC probe output.

22. The apparatus of claim 21, wherein the high frequency probe comprises:
a voltage raising circuit configured to receive an alternating current (AC) input and raise an average voltage level of the AC; and
an amplitude linearity compensation circuit configured to provide amplitude linearity compensation for an output of the voltage raising circuit,
wherein the amplitude linearity compensation circuit provides the DC probe output.

23. The high frequency probe of claim 21, wherein the voltage raising circuit is a voltage doubler circuit that includes a Schottky diode.

24. The high frequency probe of claim 21, wherein the amplitude linearity compensation circuit is an amplitude selective voltage divider that includes a diode.

25. The high frequency probe of claim 21, wherein the apparatus further comprises a housing that houses the high frequency probe and the DC voltmeter circuit.
